(19) United States
(12) Patent Application Publication
(10) Pub. No.: US 2011/0193315 A1
(43) Pub. Date: Aug. 11, 2011

(54) Tricycle With Canopy

(76) Inventor: Laura Hija J. Kim, Busan (KR)

(21) Appl. No.: 13/088,050

(22) Filed: Apr. 15, 2011

Related U.S. Application Data
(63) Continuation of application No. PCT/KR2009/005949, filed on Oct. 15, 2009.

(30) Foreign Application Priority Data
Oct. 16, 2008 (KR) 10-2008-0101755
Oct. 14, 2009 (KR) 10-2009-0097886

(51) Int. Cl. B62K 5/02; B62J 1/00; B62D 29/04; B62D 25/06; A47C 7/36; B60J 1/00; B60R 7/04; B60R 19/02; H01L 31/02; H04B 1/00; F21S 8/10; H01L 31/04

(52) U.S. Cl. 280/282; 297/195.1; 296/181.2; 296/136.11; 297/391; 296/84.1; 296/37.13; 293/102; 136/252; 381/86; 362/543

(57) ABSTRACT

The present invention relates to a tricycle having one front wheel and two rear wheels, the tricycle including: a seat frame mounted on a support frame to which the rear wheels are coupled, and having a concave seat formed at the front center thereof; side plates and a rear plate fixed at the bottom ends thereof to the both sides and the rear side of the seat frame; a plurality of space bars disposed spaced apart from each other between the side plates formed on the both sides of the seat frame; and a canopy mounted supportedly onto the plurality of space bars disposed between the side plates.

### REFERENCE TO RELATED APPLICATIONS

This is a continuation of pending International Patent Application PCT/KR2009/005949 filed on Oct. 15, 2009, which designates the United States and claims priority of Korean Patent Applications No. 10-2008-0101755 filed on Oct. 16, 2008 and No. 10-2009-0097886 filed on Oct. 14, 2009, the entire contents of which are incorporated herein by reference.

### FIELD OF THE INVENTION

The present invention relates to a tricycle with a canopy, and more particularly, to a tricycle with a canopy that is capable of protecting a rider's body from sunlight and rain, ensuring night riding safety, enabling the rider to listen to the radio, and holding his stuff like a bag into a storage space formed thereon.

### BACKGROUND OF THE INVENTION

Generally, a bicycle has a front wheel and a rear wheel mounted at the front and rear sides of a support frame, the front wheel being steered with handles and the rear wheel being driven by a pedal force applied from a rider. Accordingly, the rider pedals the bicycle in a state of balancing himself to transmit the driving force to the wheels, thereby performing the riding.

The conventional bicycle is very efficient means of transportation because it can rapidly travel a given short distance.

On the other hand, a tricycle with one front wheel and two rear wheels comes into use, but the conventional tricycle is provided just with basic functions, without having any separate functions and effects. Especially, the conventional tricycle has some problems as follows: firstly, a rider's body cannot be protected from sunlight and rain; secondly, dangers and accidents easily happen by low road visibility in night time; thirdly, it is hard for a beginner rider to easily ride the tricycle; and lastly, the rider's stuff like a bag cannot be kept on the tricycle.

### SUMMARY OF THE INVENTION

Accordingly, the present invention has been made in view of the above-mentioned problems occurring in the prior art, and it is an object of the present invention to provide a tricycle with a canopy that is capable of protecting a rider's body from sunlight and rain, ensuring night riding safety, enabling the rider to listen to the radio, and holding his stuff like a bag into a storage space formed thereon.

To accomplish the above object, according to the present invention, there is provided a tricycle having one front wheel and two rear wheels, the tricycle including: a seat frame mounted on a support frame to which the two rear wheels are coupled, and having a concave seat formed at the front center thereof; side plates and a rear plate fixed at the bottom ends thereof to the both sides and the rear side of the seat frame; a plurality of space bars disposed spaced apart from each other between the side plates formed on the both sides of the seat frame; and a canopy mounted supportedly onto the plurality of space bars disposed between the side plates.

According to the present invention, desirably, the side plates are made of a plastic material capable of watching the outside, and the rear plate has a window made of a plastic material formed separately thereon.

According to the present invention, desirably, the rear plate has a headrest mounted on the upper end thereof.

According to the present invention, desirably, the canopy is made of a waterproof fabric and is openably closed in a structure where a canopy storage case is disposed fixedly to the seat frame or the rear plate in such a manner as to fix one end of the canopy to a drive shaft to which an elastic force of a spiral spring is applied and to mount fixing bars on the other end of the canopy, the fixing bars being inserted separably into stopping holes formed along the side plates.

According to the present invention, desirably, each of the side plates has an extension portion bent downwardly at the front side thereof, the extension portion having the stopping hole formed at the lower end thereof, and the canopy has a viewing window formed toward the fixing bars at the front end portion thereof, the viewing window being made of a transparent film.

According to the present invention, desirably, the seat frame has a trunk disposed thereon and a door mounted openably on the trunk by means of hinges, so as to keep a rider's stuff thereinto.

According to the present invention, desirably, the seat frame has an audio system and a power supply part embedded in the interior thereof, the power supply part having batteries charged with AC power, and jacks for connecting a headset, a hands-free set, a mike phone and the like to the audio system, a controller for manipulating the audio system, and speakers, mounted exposedly on the inside thereof.

According to the present invention, desirably, the seat frame has lights mounted on the front and rear portions of the left and right sides thereof, the lights being connected electrically to the power supply part.

According to the present invention, desirably, each of the side plates has a wire fixedly fastened at one end thereof to the support frame to which the handles are coupled.

According to the present invention, desirably, the seat frame has a bumper mounted at the rear end thereof so as to absorb external impacts applied to the rear end thereof.

According to the present invention, desirably, the canopy has a solar cell coupled to the outside surface thereof in such a manner as to be connected electrically to the power supply part to allow the power produced therefrom to be charged to the batteries, the solar cell being selected from an inorganic solar cell, a dye-sensitized solar cell, and an organic solar cell.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a perspective view showing a tricycle with a canopy according to the present invention;

FIG. 2 is a sectional view showing the tricycle with a canopy according to the present invention; and

FIG. 3 is a sectional view showing the state where a solar cell is coupled to the surface of the canopy in the tricycle according to the present invention.

### DETAILED DESCRIPTION OF THE INVENTION

Hereinafter, an explanation on a tricycle with a canopy according to the present invention will be in detail given with reference to the attached drawings.

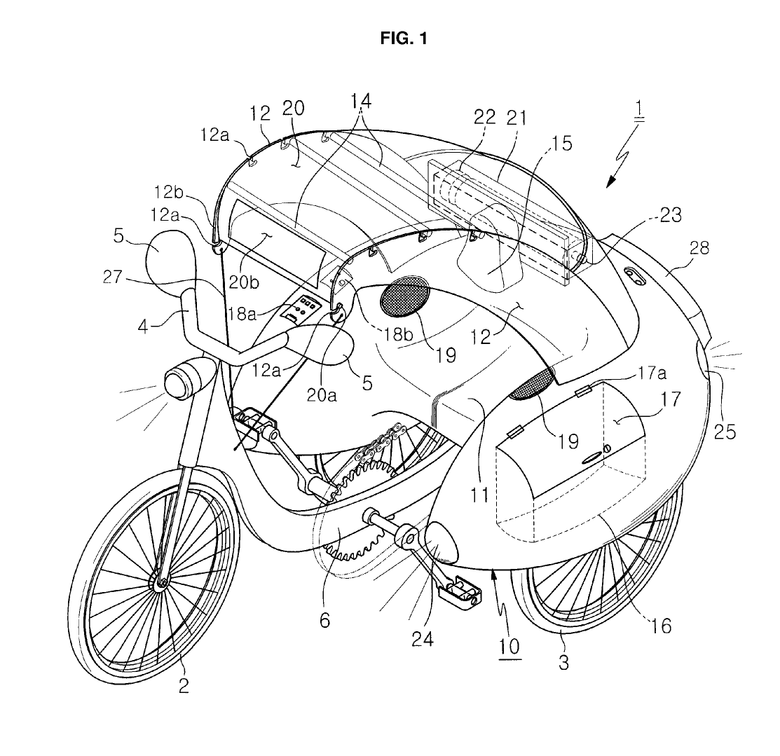

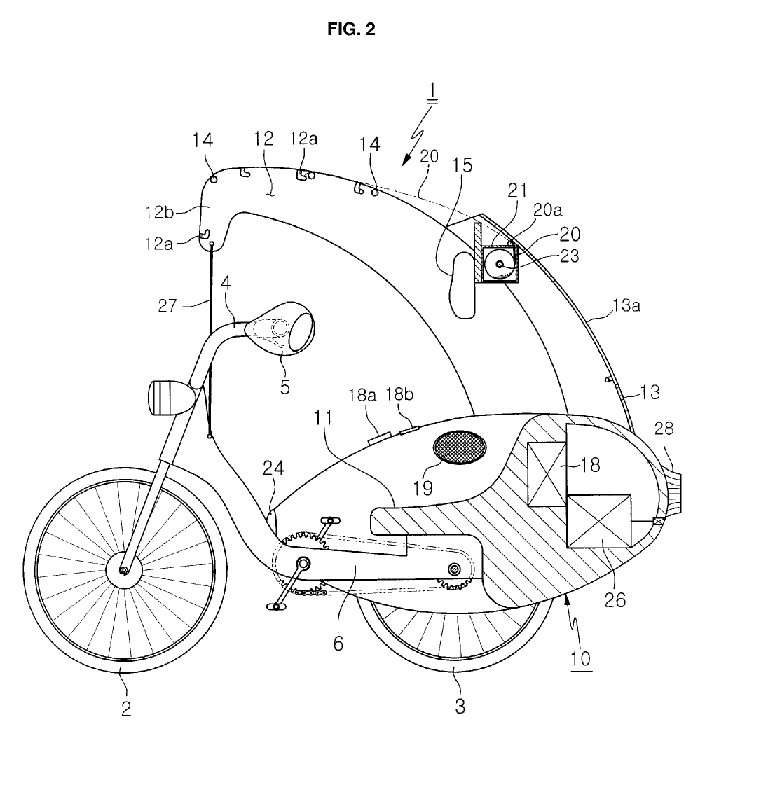

FIG. 1 is a perspective view showing a tricycle with a canopy according to the present invention, and FIG. 2 is a sectional view showing the tricycle with a canopy according to the present invention.

The present invention is related to a typical tricycle 1 having one front wheel 2 and two rear wheels 3.

Protection covers 5 adapted to protect a rider's hands are mounted on handles 4 coupled to the front wheel 2.

A seat frame 10 is mounted on a support frame 6 to which the rear wheels 3 are coupled, having a size capable of fully covering the rear wheels 3.

The seat frame 10 has a concave seat 11 formed on a front center thereof, and a cushion is disposed in the seat 11 so as to allow a rider to feel comfortable while sitting in the seat 11.

The tricycle with a canopy according to the present invention is configured to permit the rider to be protected safely from sunlight and rain.

That is, side plates 12 and a rear plate 13 are fixed at the bottom ends thereof to the both sides and the rear side of the seat frame 10. At this time, the side plates 12 are made of a plastic material capable of viewing the outside and providing a predetermined durability, and the rear plate 13 has a window 13a made of a plastic material formed separately thereon.

The two side plates 12 are in an arch shape when viewed at the side thereof, and they are kept spaced apart from each other by means of a plurality of space bars 14. A canopy 20 is mounted on the plurality of space bars 14 in such a manner as to slide along the side plates 12.

The plurality of space bars 14 are three, as shown in the drawings, but they can be increased and decreased in accordance with the size or shape of the side plates 12.

The rear plate 13 has a headrest 15 mounted on the upper end thereof so as to rest the rider's neck and head thereon, and a canopy storage case 21 is disposed at a space formed between the rear plate 13 and the headrest 15 so as to keep the canopy 20 wound in a roll shape thereinto. The canopy storage case 21 is fixed to the seat frame 10 or the rear plate 13.

The headrest 15 is of course adjustable in height by means of the manipulation of the rider.

The canopy storage case 21 has a drive shaft 23 mounted at the inside thereof in such a manner as to be driven by means of a restoring force caused by a spiral spring 22. The canopy 20 is fixed at one end thereof to the drive shaft 23.

The canopy 20 is desirably made of a waterproof fabric capable of shielding sunlight and protecting the rider's body from rain, and the canopy 20 has fixing bars 20a mounted along the front end thereof.

The fixing bars 20a are inserted separably into stopping holes 12a formed on the side plates 12.

Each of the stopping holes 12a is opened upwardly and bent toward the headrest 15 at the lower end thereof so as to prevent the fixing bar 20a inserted thereinto from being escaped therefrom.

Each of the side plates 12 has an extension portion 12b bent downwardly at the front side thereof, and the extension portion 12b also has the stopping hole 12a formed at the lower end thereof.

The canopy 20 has a viewing window 20b extended toward the fixing bars 20a at the front end portion thereof, and the viewing window 20b is fixed by insertedly fitting the fixing bars 20a to the stopping holes 12a formed on the extension portions 12b. The formation of the viewing window 20b allows the rider to observe the front and protects the rider's upper body from rain while it is raining, thereby providing safe riding.

In addition, each of the side plates 12 has a wire 27 fixedly fastened at one end thereof to the support frame 6 to which the handles 4 are coupled. The formation of the wires 27 prevents the side plates 12 from being broken by external forces like wind in the state where the side plates 12 are coupled to the canopy 20.

Fixing the wires 27 is performed freely only if there is no interference in the manipulation and operation of the handles 4.

According to the present invention, as shown in the drawings, the seat frame 10 has a trunk 16 mounted on the left side thereof and a door 17 openably mounted on the trunk 16 by means of hinges 17a. The formation of the trunk 16 allows the rider's stuff to be kept therein.

According to the present invention, also, the seat frame 10 has an audio system 18 embedded into the interior thereof, and a controller 18a for manipulating the audio system 18 and jacks 18b for connecting a headset, a hands-free set, a mike phone and the like to the audio system 18 disposed on the right side of the seat frame 10. Further, two speakers 19 are positioned on the left and right sides of the seat frame 10.

The controller 18a, the jacks 18b, and the speakers 19 are desirably mounted at the inside of the seat frame 10.

Further, the seat frame 10 has lights 24 and 25 mounted on the front and rear ends of the left and right sides thereof. The lights 24 and 25 are desirably formed of a light-emitting diode LED having relatively low power consumption.

Since the audio system 18 and the lights 24 and 25 need power capable of driving them for a predetermined period of time, the seat frame 10 has a power supply part 26 mounted at the interior thereof, in which batteries are mounted and charged with AC power.

On the other hand, the tricycle according to the present invention ensures full safety from the collision against the rear end thereof.

According to the present invention, that is, the seat frame 10 has a bumper 28 mounted at the rear end thereof so as to absorb external impacts applied to the rear end thereof, thereby previously preventing serious traffic accidents caused by the collision against the rear end of the tricycle.

The bumper 28 is made of sponge, soft hollow plastic, or the like.

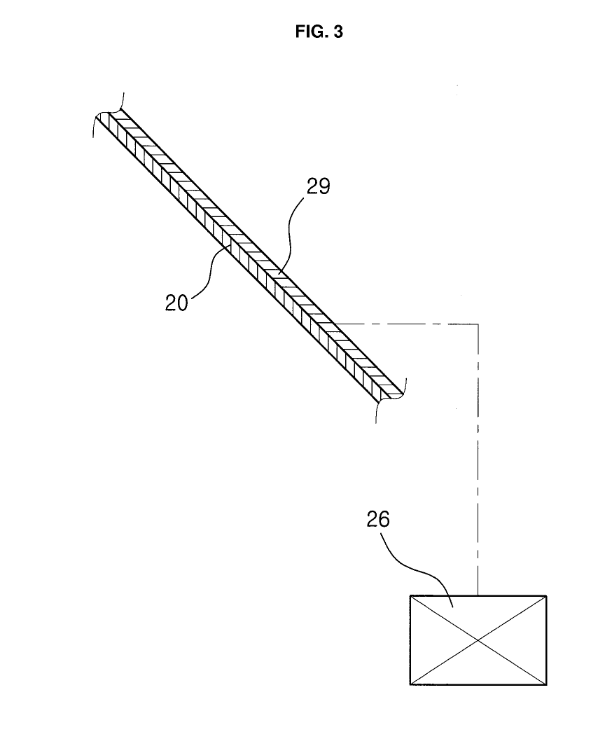

FIG. 3 is a sectional view showing the state where a solar cell is coupled to the surface of the canopy in the tricycle according to the present invention.

In the construction of the tricycle as shown in FIG. 3, that is, the canopy 20 has a solar cell 29 coupled to the outside surface thereof, and the solar cell 29 is electrically connected to the power supply part 26, thereby allowing the power produced therefrom to be charged to the batteries.

The solar cell 29 may be freely selected from those currently developed and used.

Available solar cell examples include an inorganic solar cell, a dye-sensitized solar cell, and an organic solar cell.

Examples of the inorganic solar cell include a silicon solar cell and a semiconductor solar cell such as CdTe, GaAs, CIGS and the like.

For the brevity of the description of the present invention, an explanation on the operating principle of the solar cell 29 will be not given.

As mentioned above, the tricycle according to the present invention provides the large-sized seat frame on the upper side of the two rear wheels so as to allow the rider to feel comfortable, the observable side and rear plates mounted at the side and rear of the seat frame, the canopy openably mounted along the side plates, the trunk mounted on the seat frame, the lights mounted on the front and rear sides of the seat frame, the jacks, speakers and controller for the connection to the audio system, mounted exposedly on the left and right sides of the seat frame, and the power supply part having the batteries applying power to the jacks, speakers and controller, and the audio system, embedded into the interior of the seat frame.

Further, the canopy has the solar cell coupled to the outside surface thereof in such a manner as to be connected electrically to the power supply part, thereby allowing the power produced from the solar cell to be charged to the batteries.

In more detail, the tricycle according to the present invention can be easily used even by persons who are unable to ride a bicycle due to their poor sense of balance, and can protect the rider's body from sunlight and rain by means of the formation of the canopy.

Additionally, the tricycle according to the present invention provides the storage space like the trunk on the seat frame, thereby allowing the rider's stuff to be conveniently kept thereinto, and makes use of the audio system mounted in the seat frame during riding.

Further, the tricycle according to the present invention provides the lights on the front and rear portions thereof, thereby ensuring night riding safety, and further provides exercising effects through the riding to the rider.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A tricycle having one front wheel and two rear wheels, the tricycle comprising:
a seat frame mounted on a support frame to which the rear wheels are coupled, and having a concave seat formed at the front center thereof;
side plates and a rear plate fixed at the bottom ends thereof to the both sides and the rear side of the seat frame;
a plurality of space bars disposed spaced apart from each other between the side plates formed on the both sides of the seat frame; and
a canopy mounted supportedly onto the plurality of space bars disposed between the side plates.

2. The tricycle according to claim 1, wherein the side plates are made of a plastic material capable of watching the outside, and the rear plate has a window made of a plastic material formed separately thereon.

3. The tricycle according to claim 1, wherein the rear plate has a headrest mounted on the upper end thereof.

4. The tricycle according to claim 1, wherein the canopy is made of a waterproof fabric and is openably closed in a structure where a canopy storage case is disposed fixedly to the seat frame or the rear plate in such a manner as to fix one end of the canopy to a drive shaft to which an elastic force of a spiral spring is applied and to mount fixing bars on the other end of the canopy, the fixing bars being inserted separably into stopping holes formed along the side plates.

5. The tricycle according to claim 4, wherein each of the side plates has an extension portion bent downwardly at the front side thereof, the extension portion having the stopping hole formed at the lower end thereof, and the canopy has a viewing window formed toward the fixing bars at the front end portion thereof, the viewing window being made of a transparent film.

6. The tricycle according to claim 1, wherein the seat frame has a trunk disposed thereon and a door mounted openably on the trunk by means of hinges, so as to keep a rider's stuff thereinto.

7. The tricycle according to claim 1, wherein the seat frame has an audio system and a power supply part embedded in the interior thereof, the power supply part having batteries charged with AC power, and jacks for connecting a headset, a hands-free set, a mike phone and the like to the audio system, a controller for manipulating the audio system, and speakers, mounted exposedly on the inside thereof.

8. The tricycle according to claim 7, wherein the seat frame has lights mounted on the front and rear portions of the left and right sides thereof, the lights being connected electrically to the power supply part.

9. The tricycle according to claim 1, wherein each of the side plates has a wire fixedly fastened at one end thereof to the support frame to which the handles are coupled.

10. The tricycle according to claim 1, wherein the seat frame has a bumper mounted at the rear end thereof so as to absorb external impacts applied to the rear end thereof.

11. The tricycle according to claim 1, wherein the canopy has a solar cell coupled to the outside surface thereof in such a manner as to be connected electrically to the power supply part to allow the power produced therefrom to be charged to the batteries, the solar cell being selected from an inorganic solar cell, a dye-sensitized solar cell, and an organic solar cell.
